(19) United States
(12) Patent Application Publication
(10) Pub. No.: US 2008/0014124 A1
(43) Pub. Date: Jan. 17, 2008

(54) Sample processing devices, systems and methods

(75) Inventor: Zbigniev Skrzypczynski, Verona, WI (US)

Correspondence Address: Casimir Jones, S.C., 440 Science Drive, Suite 203, Madison, WI, 53711, US

(73) Assignee: Third Wave Technologies, Inc., Madison, WI (US)

(21) Appl. No.: 11/498,670

(22) Filed: Aug. 3, 2006

Related U.S. Application Data
(60) Provisional application No. 60/705,658, filed on Aug. 4, 2005.

(51) Int. Cl. B81B 7/00

(52) U.S. Cl. 422/103; 422/68.1

(57) ABSTRACT

The present invention provides microfluidic sample processing systems and devices comprising a plurality chambers and channels in fluidic communication with a sample loading port, and methods of making and employing such systems and devices. Preferably, the systems and devices of the present invention are configured such that temperature changes in the chambers allows liquid sample in the sample loading port to be drawn into the channels.

The present application claims priority to U.S. Provisional application Ser. No. 60/705,658, filed Aug. 4, 2005, which is herein incorporated by reference.

### FIELD OF THE INVENTION

The present invention relates to microfluidic sample processing systems and devices comprising a plurality chambers and channels in fluidic communication with a sample loading port, and methods of making and employing such systems and devices. Preferably, the systems and devices of the present invention are configured such that temperature changes in the chambers allows liquid sample in the sample loading port to be drawn into the channels.

### BACKGROUND

Considerable advances have been made in microfluidic device technology over the past 50 years. In general, as microfluidic systems are produced of decreasing size and increasing complexity. The cost and difficulty of precise manufacture of such devices has increased concomitantly. Advanced features for microfluidic volume control, such as microvalves, pumps, mixers, turbines, and the like, have contributed to the increase in complexity and cost of these systems. Due to their high complexity and sensitivity, these delicate systems are not amendable to mass production or use in the field, where suboptimal conditions may make their use impracticable. What is needed, therefore, is a microfluidic sample processing device capable of precise liquid volume control, and precise temperature control, that is simple and durable, and amenable to mass production and use in the field.

### SUMMARY OF THE INVENTION

The present invention provides microfluidic sample processing systems and devices comprising a plurality chambers and channels in fluidic communication with a sample loading port, and methods of making and employing such systems and devices. Preferably, the systems and devices of the present invention are configured such that temperature changes in the chambers allows liquid sample in the sample loading port to be drawn into the channels.

In some embodiments, the present invention provides sample processing systems and devices comprising; a) a plate component, wherein the plate component comprises; i) a top surface and a bottom surface; ii) a sample loading port extending from the top surface to the bottom surface, and iii) a plurality of un-enclosed micro-reactors formed in the bottom surface, wherein each of the un-enclosed micro-reactors comprises; A) a chamber, and B) a channel, wherein the channel comprises a first channel end adjacent to the chamber and a second channel end adjacent to the sample loading port, and b) a cover component, wherein the cover component is configured to attach to the bottom surface of the plate component such that a plurality of enclosed micro-reactors are generated.

In certain embodiments, the present invention provides sample processing systems and devices comprising; a) a plate component, wherein the plate component comprises; i) a top surface and a bottom surface; ii) a sample loading port extending from the top surface to the bottom surface, and iii) a plurality of micro-reactors, wherein each of the micro-reactors comprises; A) a chamber comprising gas at a first temperature, and B) a channel, wherein the channel comprises a first channel end adjacent to the chamber and a second channel end adjacent to the sample loading port, and b) a plate support component configured to be secured to the bottom surface of the plate component, wherein the plate component comprises at least one accessory element selected from the group consisting of: a chamber temperature control element, a channel sealing element, and a channel temperature control element.

In other embodiments, the present invention provides methods (e.g. of loading a sample in a sample processing system or device) comprising; a) providing, i) a sample processing system comprising; A) a sample loading port, and B) a plurality of micro-reactors, wherein each of the micro-reactors comprises; I) a chamber comprising gas, wherein the chamber is at a first temperature, and II) a channel, wherein the channel comprises a first channel end adjacent to the chamber and a second channel end adjacent to the sample loading port, and ii) a liquid sample; and b) changing (e.g. increasing) the first temperature in the chamber to a second temperature such that the gas expands; c) adding the liquid sample to the sample loading port, and d) reducing the second temperature in the chamber such that the gas contracts causing a portion of the liquid sample to be drawn into the channels.

In certain embodiments, reducing the second temperature comprises positioning the sample processing device in an environment where heat in the chamber is lost to the environment (e.g. leaving it in an area where the ambient temperature is lower than the second temperature or moving the device to such an area). In other embodiments, reducing the second temperature comprises removing a heat source used for increasing the first temperature. In some embodiments, reducing the second temperature comprises exposing the chamber to a chamber temperature control element capable of cooling the chamber. In particular embodiments, increasing the first temperature is accomplished with a chamber temperature control element capable of heating the chamber.

In some embodiments, the present invention provides methods of making a sample processing device or system, comprising; a) providing; i) a plate component comprising a top surface and a bottom surface, and ii) a cover component configured to be secured to the bottom surface of the plate component, and/or iii) a plate support component configured to be secured to the bottom surface of said plate component; and b) generating a sample loading port in the plate component, wherein the sample loading port extends from the top surface to the bottom surface of the plate component, and c) forming a plurality of un-enclosed micro-reactors in the bottom surface of the plate component, wherein each of the un-enclosed micro-reactors comprises: i) a chamber, and ii) a channel, wherein the channel comprises a first channel end adjacent to the chamber and a second channel end adjacent to the sample loading port; and d) attaching the cover component and/or the plate support component, to the bottom surface of the plate component such that a plurality of enclosed micro-reactors are generated. In particular embodiments, the un-enclosed micro-reactors are formed in the plate component by micro-embossing, micro-etching, or similar techniques.

In certain embodiments, the chambers have a larger volume than the channels (e.g. such that when the chambers cool, a sufficient force is generated to draw liquid sample into the channels from the sample loading port). In other embodiments, the cover component is a sealable cover component (e.g. the cover component comprises regions that can be melted or otherwise manipulated such that chambers and/or channels can be sealed off from each other). In some embodiments, the cover component is attached to the plate component. In additional embodiments, the cover component is not attached to the plate component. In particular embodiments, the channels comprise dried assay reagents (e.g. for performing biological or chemical reactions).

In some embodiments, the channels are in fluidic communication with the sample loading port and the chamber. In particular embodiments, the chambers are only in fluidic communication with one channel (e.g. the chambers are closed off, such that the only point of entry or exit for gas or fluid is via one associated channel). In further embodiments, the sample processing devices and systems further comprise sealable material, wherein the sealable material is located at the first channel end, the second channel end, or both the first and second channel ends. Preferably, when the sealable material is exposed to heat (or other force such as radiation, etc.) the material melts such that is blocks at least one end of a channel.

In other embodiments, the sample processing systems and devices further comprise a plate support component configured to be secured to the bottom surface of the plate component. In certain embodiments, the plate component is secured to the bottom surface of the plate component such that at least a portion of the cover component is between the plate support component and the plate component. In some embodiments, the plate support component comprises a plurality of channel sealing elements. In other embodiments, the plurality of channel sealing elements are located near the first and second channel ends when the plate component is secured to the bottom surface of the plate component. In particular embodiments, the channel sealing elements are configured to heat at a portion of the cover component (e.g. such that a portion of the cover component melts and seals at least one end of a channel) or configured to heat sealable material if present in the channels.

In some embodiments, the plate support component comprises a plurality of chamber temperature control elements. In particular embodiments, the plurality of chamber temperature control elements are located near the chambers when the plate component is secured to the bottom surface of the plate component (e.g. within about 0.5, 1, or 2 mm). In further embodiments, the chamber temperature control elements are capable of causing gas (or liquid) inside the chambers to expand or contract. In other embodiments, the system or device comprises a liquid sample in the sample loading port, wherein the chamber temperature control elements are capable of causing the liquid sample to enter the channels by heating or cooling gas (or liquid) inside the chambers.

In additional embodiments, the plate support comprises a plurality of channel temperature control elements. In further embodiments, the plurality of channel temperature control elements are located near (e.g. within about 0.5, 1, or 2 mm) the channels when the plate component is secured to the bottom surface of the plate component.

In other embodiments, the plate component further comprises a plurality of detection ports configured to allow reactions in the channels to be monitored (e.g., by a fluorescent detection device). In further embodiments, the channels contain a liquid sample. In particular embodiments, the first and second channel ends are sealed such that the liquid sample is contained within the channels.

In some embodiments, the diameter of the channels is about 50-400 μm, about 800-10 μm, about 75-150 μm, or about 100 μm. In other embodiments, the channels have a length of about 1-40 mm (e.g. 1, 3, 5, 7.5, 10, 15, 25, 35, etc.). In particular embodiments, the plate component contain at least two micro-reactors, or at least 5, at least 10, at least 25, at least about 45, or at least about 100 micro-reactors (e.g. 5, 10, 15, 25, 50, 75, 90, 100, 1000, or 10,000 micro-reactors). In further embodiments, the plurality of micro-reactors extend from the sample loading port in a radial manner. In other embodiments, the channels are separated by about 100-300 μm in the plate component. In some embodiments, the sample loading port has a diameter of about 1-20 mm (e.g. 3 mm, 4 mm, 5 mm, 6 mm, 7, mm, 8 mm, 10 mm, 15 mm, or 20 mm). In certain embodiments, the plate component has a length of about 20-200 mm (e.g. 20 mm, 40 mm, 75 mm, 100 mm, or 150 mm). In some embodiments, the plate component has a width of about 10-100 mm (e.g. 10, 25, 50, 75, or 100 mm). In other embodiments, the plate component has a depth of about 1-20 mm (e.g. 1, 3, 5, 10, 15, or 20 mm). In further embodiments, the plate component further comprises a second, third, fourth, tenth, etc., sample loading port.

In some embodiments, the sample processing system further comprises a plate support component, wherein the plate component comprises at least one accessory element selected from the group consisting of: a chamber temperature control element (e.g. at least one chamber temperature control for each chamber in the plate component), a channel sealing element, and a channel temperature control element (e.g., at least one channel temperature control element for each channel in the plate component).

In particular embodiments, the channels comprise assay reagents (e.g. dried assay reagents). In some embodiments, the assay reagents comprise a label. In further embodiments, the assay reagents react with the portion of the liquid sample drawn into the channels in order to detect the presence or absence of a target in the sample. In other embodiments, the assay reagents comprise nucleic acid detection reagents that are configured for carrying out a nucleic acid detection assay in the presence of the liquid sample. In additional embodiments, the assay reagents comprise non-amplified oligonucleotide detection assay reagents. In certain embodiments, the assay reagents comprise INVADER assay reagents. In some embodiments, the nucleic acid detection reagents comprise INVADER oligonucleotides, primary probe oligonucleotides, FEN enzymes, and FRET cassettes. In additional embodiments, the nucleic acid detection reagents comprise first and second oligonucleotides and a cleavage agent, wherein the first and second oligonucleotides are configured to form an invasive cleavage structure with a target sequence (e.g. potential present in the liquid sample), and wherein the cleavage agent is capable of cleaving the first oligonucleotide when the cleavage structure is formed. In other embodiments, the first oligonucleotide comprises a 5′ portion and a 3′ portion, wherein the 3′ portion is configured to hybridize to the target sequence, and wherein the 5′ portion is configured to not hybridize to the target sequence. In some embodiments, the second oligonucleotide comprises a 5′ portion and a 3′ portion, wherein the 5′ portion is configured to hybridize to the target sequence, and wherein the 3′ portion is configured to not hybridize to the target sequence.

### DEFINITIONS

To facilitate an understanding of the present invention, a number of terms and phrases are defined below:

As used herein, the term “INVADER assay reagents” refers to one or more reagents for detecting target sequences, said reagents comprising nucleic acid molecules capable of forming an invasive cleavage structure in the presence of the target sequence. In some embodiments, the INVADER assay reagents further comprise an agent for detecting the presence of an invasive cleavage structure (e.g., a cleavage agent). In some embodiments, the oligonucleotides comprise first and second oligonucleotides, said first oligonucleotide comprising a 5′ portion complementary to a first region of the target nucleic acid and said second oligonucleotide comprising a 3′ portion and a 5′ portion, said 5′ portion complementary to a second region of the target nucleic acid downstream of and contiguous to the first portion. In some embodiments, the 3′ portion of the second oligonucleotide comprises a 3′ terminal nucleotide not complementary to the target nucleic acid. In preferred embodiments, the 3′ portion of the second oligonucleotide consists of a single nucleotide not complementary to the target nucleic acid. INVADER assay reagents may be found, for example, in U.S. Pat. Nos. 5,846,717; 5,985,557; 5,994,069; 6,001,567; 6,913,881; and 6,090,543, WO 97/27214, WO 98/42873, Lyamichev et al., Nat. Biotech., 17:292 (1999), Hall et al., PNAS, USA, 97:8272 (2000), each of which is herein incorporated by reference in their entirety for all purposes.

In some embodiments, INVADER assay reagents are configured to detect a target nucleic acid sequence comprising first and second non-contiguous single-stranded regions separated by an intervening region comprising a double-stranded region. In preferred embodiments, the INVADER assay reagents comprise a bridging oligonucleotide capable of binding to said first and second non-contiguous single-stranded regions of a target nucleic acid sequence. In particularly preferred embodiments, either or both of said first or said second oligonucleotides of said INVADER assay reagents are bridging oligonucleotides.

In some embodiments, the INVADER assay reagents further comprise a solid support. For example, in some embodiments, the one or more oligonucleotides of the assay reagents (e.g., first and/or second oligonucleotide, whether bridging or non-bridging) is attached to said solid support. In some embodiments, the INVADER assay reagents further comprise a buffer solution. In some preferred embodiments, the buffer solution comprises a source of divalent cations (e.g., Mn²⁺ and/or Mg²⁺ ions). Individual ingredients (e.g., oligonucleotides, enzymes, buffers, target nucleic acids) that collectively make up INVADER assay reagents are termed “INVADER assay reagent components.” In some embodiments, the INVADER assay reagents further comprise a third oligonucleotide complementary to a third portion of the target nucleic acid upstream of the first portion of the first target nucleic acid. In yet other embodiments, the INVADER assay reagents further comprise a target nucleic acid. In some embodiments, the INVADER assay reagents further comprise a second target nucleic acid. In yet other embodiments, the INVADER assay reagents further comprise a third oligonucleotide comprising a 5′ portion complementary to a first region of the second target nucleic acid. In some specific embodiments, the 3′ portion of the third oligonucleotide is covalently linked to the second target nucleic acid. In other specific embodiments, the second target nucleic acid further comprises a 5′ portion, wherein the 5′ portion of the second target nucleic acid is the third oligonucleotide. In still other embodiments, the INVADER assay reagents further comprise an ARRESTOR molecule (e.g., ARRESTOR oligonucleotide).

In some preferred embodiments, the INVADER assay reagents further comprise reagents for detecting a nucleic acid cleavage product. In some embodiments, one or more oligonucleotides in the INVADER assay reagents comprise a label. In some preferred embodiments, said first oligonucleotide comprises a label. In other preferred embodiments, said third oligonucleotide comprises a label. In particularly preferred embodiments, the reagents comprise a first and/or a third oligonucleotide labeled with moieties that produce a fluorescence resonance energy transfer (FRET) effect.

In some embodiments one or more the INVADER assay reagents may be provided in a predispensed format (e.g., premeasured for use in a step of the procedure without re-measurement or re-dispensing). In some embodiments, selected INVADER assay reagent components are mixed and predispensed together. In preferred embodiments, predispensed assay reagent components are predispensed and are provided in a channel of a sample processing device or system.

The term “label” as used herein refers to any atom or molecule that can be used to provide a detectable (preferably quantifiable) effect, and that can be attached to a nucleic acid or protein. Labels include but are not limited to dyes; radiolabels such as ³²P; binding moieties such as biotin; haptens such as digoxgenin; luminogenic, phosphorescent or fluorogenic moieties; mass tags; and fluorescent dyes alone or in combination with moieties that can suppress (“quench”) or shift emission spectra by fluorescence resonance energy transfer (FRET). FRET is a distance-dependent interaction between the electronic excited states of two molecules (e.g., two dye molecules, or a dye molecule and a non-fluorescing quencher molecule) in which excitation is transferred from a donor molecule to an acceptor molecule without emission of a photon. (Stryer et al., 1978, Ann. Rev. Biochem., 47:819; Selvin, 1995, Methods Enzymol., 246:300, each incorporated herein by reference). As used herein, the term “donor” refers to a fluorophore that absorbs at a first wavelength and emits at a second, longer wavelength. The term “acceptor” refers to a moiety such as a fluorophore, chromophore, or quencher that has an absorption spectrum that overlaps the donor's emission spectrum, and that is able to absorb some or most of the emitted energy from the donor when it is near the donor group (typically between 1-100 nm). If the acceptor is a fluorophore, it generally then re-emits at a third, still longer wavelength; if it is a chromophore or quencher, it then releases the energy absorbed from the donor without emitting a photon. In some embodiments, changes in detectable emission from a donor dye (e.g. when an acceptor moiety is near or distant) are detected. In some embodiments, changes in detectable emission from an acceptor dye are detected. In preferred embodiments, the emission spectrum of the acceptor dye is distinct from the emission spectrum of the donor dye such that emissions from the dyes can be differentiated (e.g., spectrally resolved) from each other.

In some embodiments, a donor dye is used in combination with multiple acceptor moieties. In a preferred embodiment, a donor dye is used in combination with a non-fluorescing quencher and with an acceptor dye, such that when the donor dye is close to the quencher, its excitation is transferred to the quencher rather than the acceptor dye, and when the quencher is removed (e.g., by cleavage of a probe), donor dye excitation is transferred to an acceptor dye. In particularly preferred embodiments, emission from the acceptor dye is detected. See, e.g., Tyagi, et al., Nature Biotechnology 18:1191 (2000), which is incorporated herein by reference.

Labels may provide signals detectable by fluorescence (e.g., simple fluorescence, FRET, time-resolved fluorescence, fluorescence polarization, etc.), radioactivity, colorimetry, gravimetry, X-ray diffraction or absorption, magnetism, enzymatic activity, characteristics of mass or behavior affected by mass (e.g., MALDI time-of-flight mass spectrometry), and the like. A label may be a charged moiety (positive or negative charge) or alternatively, may be charge neutral. Labels can include or consist of nucleic acid or protein sequence, so long as the sequence comprising the label is detectable.

As used herein, the term “distinct” in reference to signals refers to signals that can be differentiated one from another, e.g., by spectral properties such as fluorescence emission wavelength, color, absorbance, mass, size, fluorescence polarization properties, charge, etc., or by capability of interaction with another moiety, such as with a chemical reagent, an enzyme, an antibody, etc.

As used herein, the terms “complementary” or “complementarity” are used in reference to polynucleotides (i.e., a sequence of nucleotides such as an oligonucleotide or a target nucleic acid) related by the base-pairing rules. For example, for the sequence “5′-A-G-T-3′,” is complementary to the sequence “3′-T-C-A-5′.” Complementarity may be “partial,” in which only some of the nucleic acids' bases are matched according to the base pairing rules. Or, there may be “complete” or “total” complementarity between the nucleic acids. The degree of complementarity between nucleic acid strands has significant effects on the efficiency and strength of hybridization between nucleic acid strands. This is of particular importance in amplification reactions, as well as detection methods that depend upon binding between nucleic acids. Either term may also be used in reference to individual nucleotides, especially within the context of polynucleotides. For example, a particular nucleotide within an oligonucleotide may be noted for its complementarity, or lack thereof, to a nucleotide within another nucleic acid strand, in contrast or comparison to the complementarity between the rest of the oligonucleotide and the nucleic acid strand.

The term “oligonucleotide” as used herein is defined as a molecule comprising two or more deoxyribonucleotides or ribonucleotides, preferably at least 5 nucleotides, more preferably at least about 10-15 nucleotides and more preferably at least about 15 to 30 nucleotides or longer. The exact size will depend on many factors, which in turn depend on the ultimate function or use of the oligonucleotide. The oligonucleotide may be generated in any manner, including chemical synthesis, DNA replication, reverse transcription, PCR, or a combination thereof. In some embodiments, oligonucleotides that form invasive cleavage structures are generated in a reaction (e.g., by extension of a primer in an enzymatic extension reaction).

Because mononucleotides are reacted to make oligonucleotides in a manner such that the 5′ phosphate of one mononucleotide pentose ring is attached to the 3′ oxygen of its neighbor in one direction via a phosphodiester linkage, an end of an oligonucleotide is referred to as the “5′ end” if its 5′ phosphate is not linked to the 3′ oxygen of a mononucleotide pentose ring and as the “3′ end” if its 3′ oxygen is not linked to a 5′ phosphate of a subsequent mononucleotide pentose ring. As used herein, a nucleic acid sequence, even if internal to a larger oligonucleotide, also may be said to have 5′ and 3′ ends. A first region along a nucleic acid strand is said to be upstream of another region if the 3′ end of the first region is before the 5′ end of the second region when moving along a strand of nucleic acid in a 5′ to 3′ direction.

When two different, non-overlapping oligonucleotides anneal to different regions of the same linear complementary nucleic acid sequence, and the 3′ end of one oligonucleotide points towards the 5′ end of the other, the former may be called the “upstream” oligonucleotide and the latter the “downstream” oligonucleotide. Similarly, when two overlapping oligonucleotides are hybridized to the same linear complementary nucleic acid sequence, with the first oligonucleotide positioned such that its 5′ end is upstream of the 5′ end of the second oligonucleotide, and the 3′ end of the first oligonucleotide is upstream of the 3′ end of the second oligonucleotide, the first oligonucleotide may be called the “upstream” oligonucleotide and the second oligonucleotide may be called the “downstream” oligonucleotide.

The term “cleavage structure” as used herein, refers to a structure that is formed by the interaction of at least one probe oligonucleotide and a target nucleic acid, forming a structure comprising a duplex, the resulting structure being cleavable by a cleavage agent, including but not limited to an enzyme. The cleavage structure is a substrate for specific cleavage by the cleavage agent in contrast to a nucleic acid molecule that is a substrate for non-specific cleavage by agents such as phosphodiesterases which cleave nucleic acid molecules without regard to secondary structure (i.e., no formation of a duplexed structure is required).

The term “cleavage agent” as used herein refers to any moiety that is capable of cleaving a cleavage structure, including but not limited to enzymes. “Structure-specific nucleases” or “structure-specific enzymes” are enzymes that recognize specific secondary structures in a nucleic molecule and cleave these structures. The cleavage agent of the invention cleave a nucleic acid molecule in response to the formation of cleavage structures; it is not necessary that the cleavage agent cleave the cleavage structure at any particular location within the cleavage structure.

The cleavage agent may include nuclease activity provided from a variety of sources including the CLEAVASE enzymes, the FEN-1 endonucleases (including RAD2 and XPG proteins), Taq DNA polymerase and E. coli DNA polymerase I. The cleavage agent may include enzymes having 5′ nuclease activity (e.g., Taq DNA polymerase (DNAP), E. coli DNA polymerase I). The cleavage agent may also include modified DNA polymerases having 5′ nuclease activity but lacking synthetic activity. Examples of cleavage agent suitable for use in the method and kits of the present invention are provided in U.S. Pat. Nos. 5,614,402; 5,795,763; 5,843,669; 6,090,606; 6,090,543; PCT Appln. Nos WO 98/23774; WO 02/070755A2; WO0190337A2; and WO 2003/073067, each of which is herein incorporated by reference it its entirety.

The term “cleavage products” as used herein, refers to products generated by the reaction of a cleavage agent with a cleavage structure (i.e., the treatment of a cleavage structure with a cleavage agent).

The term “target nucleic acid,” when used in reference to an invasive cleavage reaction, refers to a nucleic acid molecule containing a sequence that has at least partial complementarity with at least a probe oligonucleotide and may also have at least partial complementarity with an INVADER oligonucleotide. The target nucleic acid may comprise single- or double-stranded DNA or RNA.

The term “non-target cleavage product” refers to a product of a cleavage reaction that is not derived from the target nucleic acid. As discussed above, in the methods of the present invention, cleavage of the cleavage structure generally occurs within the probe oligonucleotide. The fragments of the probe oligonucleotide generated by this target nucleic acid-dependent cleavage are “non-target cleavage products.”The term “probe oligonucleotide,” when used in reference to an invasive cleavage reaction, refers to an oligonucleotide that interacts with a target nucleic acid to form a cleavage structure in the presence or absence of an INVADER oligonucleotide. When annealed to the target nucleic acid, the probe oligonucleotide and target form a cleavage structure and cleavage occurs within the probe oligonucleotide.

The term “INVADER oligonucleotide” refers to an oligonucleotide that hybridizes to a target nucleic acid at a location near the region of hybridization between a probe and the target nucleic acid, wherein the INVADER oligonucleotide comprises a portion (e.g., a chemical moiety, or nucleotide—whether complementary to that target or not) that overlaps with the region of hybridization between the probe and target. In some embodiments, the INVADER oligonucleotide contains sequences at its 3′ end that are substantially the same as sequences located at the 5′ end of a probe oligonucleotide.

The term “cassette,” when used in reference to an invasive cleavage reaction, as used herein refers to an oligonucleotide or combination of oligonucleotides configured to generate a detectable signal in response to cleavage of a probe oligonucleotide in an INVADER assay. In preferred embodiments, the cassette hybridizes to a non-target cleavage product from cleavage of the probe oligonucleotide to form a second invasive cleavage structure, such that the cassette can then be cleaved.

In some embodiments, the cassette is a single oligonucleotide comprising a hairpin portion (i.e., a region wherein one portion of the cassette oligonucleotide hybridizes to a second portion of the same oligonucleotide under reaction conditions, to form a duplex). In other embodiments, a cassette comprises at least two oligonucleotides comprising complementary portions that can form a duplex under reaction conditions. In preferred embodiments, the cassette comprises a label. In particularly preferred embodiments, cassette comprises labeled moieties that produce a fluorescence resonance energy transfer (FRET) effect.

As used herein, the phrase “non-amplified oligonucleotide detection assay” refers to a detection assay configured to detect the presence or absence of a particular polymorphism (e.g., SNP, repeat sequence, etc.) in a target sequence (e.g. genomic DNA) that has not been amplified (e.g. by PCR), without creating copies of the target sequence. A “non-amplified oligonucleotide detection assay” may, for example, amplify a signal used to indicate the presence or absence of a particular polymorphism in a target sequence, so long as the target sequence is not copied.

The term “sample” in the present specification and claims is used in its broadest sense. On the one hand it is meant to include a specimen or culture (e.g., microbiological cultures). On the other hand, it is meant to include both biological and environmental samples. A sample may include a specimen of synthetic origin.

Biological samples may be animal, including human, fluid, solid (e.g., stool) or tissue, as well as liquid and solid food and feed products and ingredients such as dairy items, vegetables, meat and meat by-products, and waste. Biological samples may be obtained from all of the various families of domestic animals, as well as feral or wild animals, including, but not limited to, such animals as ungulates, bear, fish, lagamorphs, rodents, etc.

Environmental samples include environmental material such as surface matter, soil, water and industrial samples, as well as samples obtained from food and dairy processing instruments, apparatus, equipment, utensils, disposable and non-disposable items. These examples are not to be construed as limiting the sample types applicable to the present invention.

### DESCRIPTION OF THE DRAWINGS

FIG. 1A shows one embodiment of a plate component 20 with three sample loading ports 60. FIG. 1B shows one embodiment of a plate component 20, with a sample loading port 60 connected to a plurality of micro-reactors 50. FIG. 1C shows one embodiment of the spacing of channels 30 in the plate component 20.

FIG. 2A shows one embodiment of a plate component 20 with a sample loading port 60 and two un-enclosed micro-reactors 55 composed of a channel 30 and a chamber 40. FIG. 2B shows a micro-reactor 50 in fluidic communication with a sample loading port 60.

FIG. 3 shows a cut-away view of one embodiments of a sample processing system and device 10 with a cover component 70 attached to a plate component 20. Also shown are two enclosed micro-reactors 56 formed in the bottom surface 26 of plate component 20.

FIG. 4A shows a cut-away view of one embodiment of a sample processing system 10 with a plate support 80 configured to be attached to a plate component 20 with a cover component 70 in between. The plate component 80 is shown with a plurality of channel sealing elements 100 and chamber temperature control elements 90. FIG. 4B show one embodiments of the sample processing system with a sample 130 loaded in the sample loading port 60 and in the channels 30.

FIG. 5A shows a cut-away view of one embodiment of a sample processing device 10, where the channels 30 one of the ends contains sealable material 110. FIG. 5B shows a cut-away view of one embodiment of a sample processing device 10, including a plate support component 80 which includes a plurality of channel temperature control elements 150, and a plate component 20 with a plurality of detection ports 120.

FIG. 6 shows a schematic diagram of exemplary INVADER oligonucleotides, probe oligonucleotides and FRET cassettes for detecting a wild-type single-nucleotide polymorphism.

### DESCRIPTION OF THE INVENTION

The present invention provides microfluidic sample processing systems and devices comprising a plurality chambers and channels in fluidic communication with a sample loading port, and methods of making and employing such systems and devices. Preferably, the systems and devices of the present invention are configured such that temperature changes in the chambers allows liquid sample in the sample loading port to be drawn into the channels. For convenience, the description of the invention is presented in the following sections: I) Exemplary Sample Processing Devices and Systems; II) Sample Processing Devices and Systems; and III) Preferred Reagents for use with the Sample Processing Devices and Systems.

I. Exemplary Sample Processing Devices and Systems

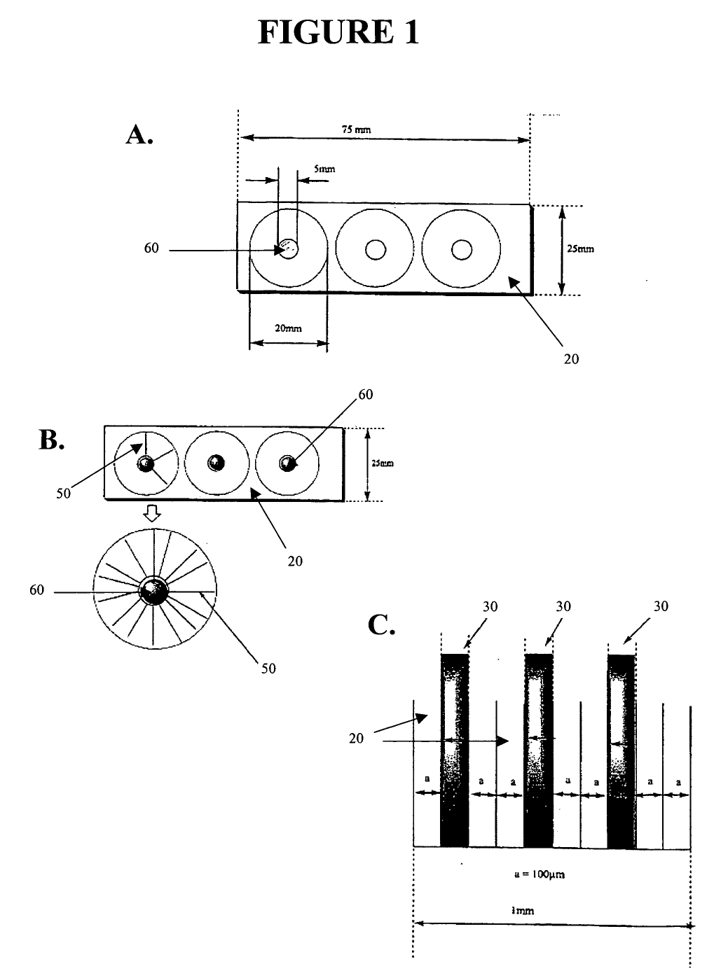

FIGS. 1-6 show exemplary embodiments of various features of the sample processing devices and systems of the present invention. FIG. 1A shows a plate component 20 with three sample loading openings 60 located therein. The plate component 20 is not limited to a particular size, but may be about the size of a standard microscope slide (e.g. about 25 mm×75 mm, and 1-10 mm in height). The plate component may be made of any suitable material, and is preferably composed of polymeric material such as polystyrene, PMMA, polyethylene, or similar material. Depending on the particular application, the surface of the plate component may be hydrophobic, neutral, or hydrophilic. The sample loading openings 60 may extend all the way through the plate component (as shown in FIGS. 1-6) or may extend only party way through. The sample loading opening 60 is not limited in size (e.g., 5 mm is shown as an exemplary size in these figures).

FIG. 1B shows a plurality of micro-reactors 50 (comprising a channel 30 and a chamber 40) extending radially from the loading port 60. The channels 30 may have any width and depth, preferably about 100 μm×100 μm or a similar size (e.g. a width and/or depth of between 10-500 μm). The channels 30 may extend from the loading port 60 in a radial manner (as shown in FIG. 1B) or in any other configuration. As shown in FIG. 1C, the channels 30 may be spaced apart in a regular manner (e.g. such that there is 200 μm between the channels). In the exemplary embodiments in the figures, using a radial construction pattern, three sample loading ports 5 mm in diameter could be accommodated on a 25 mm×75 mm plate component with about 47 channels extending therefrom if a 200 μm space is left between channels (for a total of about 141 channels).

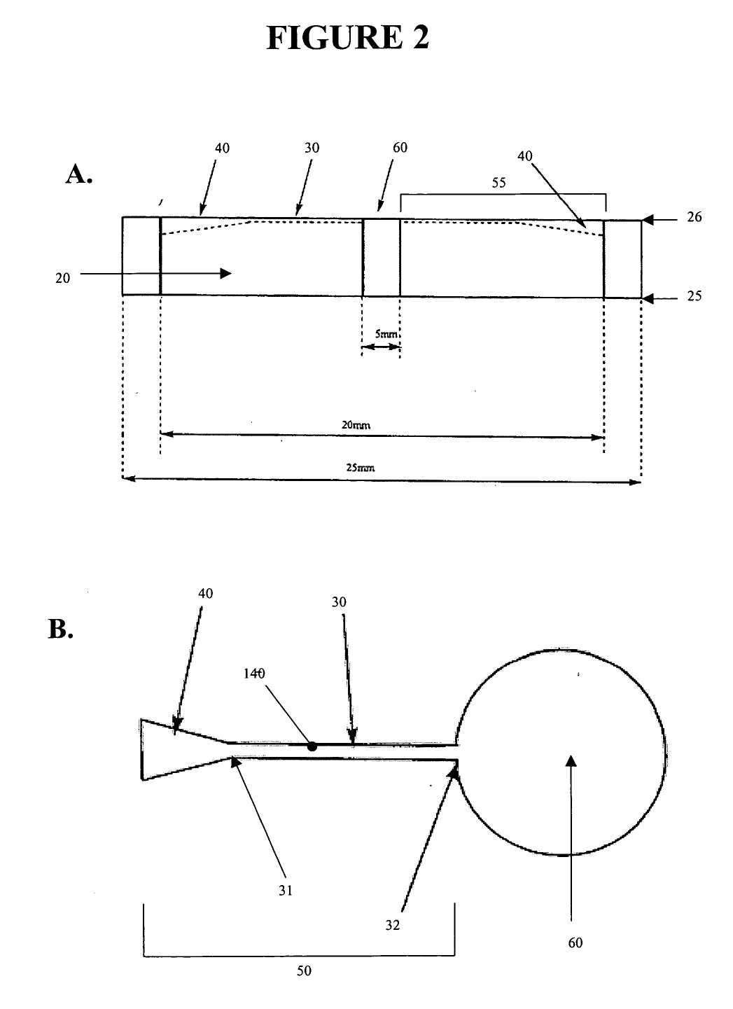

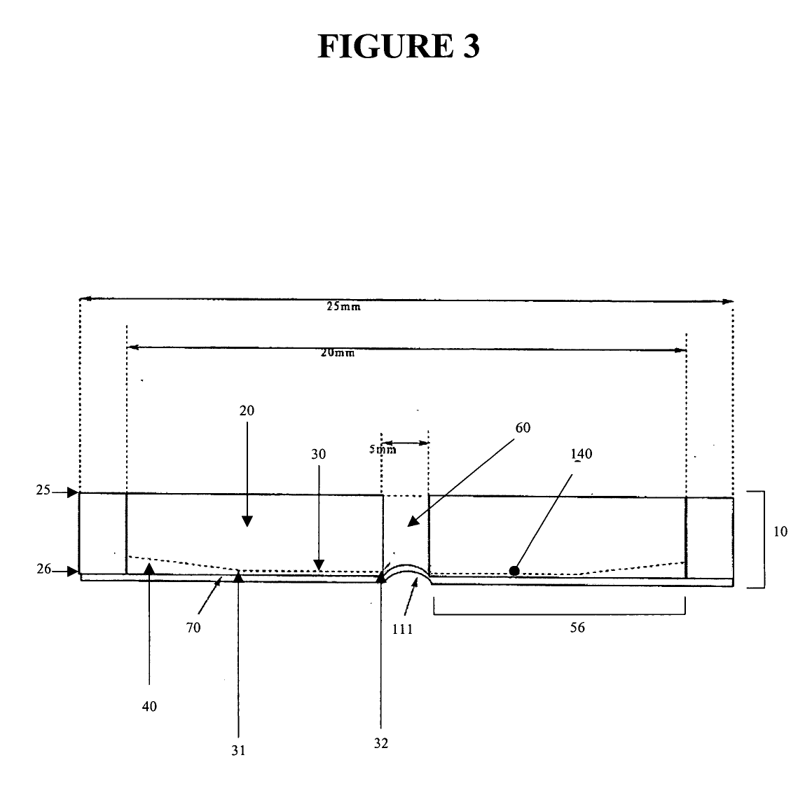

FIG. 2A shows a side view of plate component 20, which has a top surface 25 and a bottom surface 26, a sample loading port 60 cut therethrough, and two channels 30 extending therefrom. Each channel 30 ends with a chamber 40. Preferably, the chamber 40 has a larger volume than its associated channel 30. Together, the channel and chamber can be termed a “micro-reactor” 50. An unenclosed micro-reactor 55 (e.g., the bottom surface of the channels and chambers is open) is shown in FIG. 2B, with the second end of the channel 32 open to the sample loading port 60. As shown in this figure, the channel 30 has a first end 31 that is open to the chamber 40 and second end 32 that is open to the sample loading port 60. The channels 30 and chambers 40 may be etched in the surface of the plate component 20. The channels and chambers may be enclosed as described below in FIG. 3. The channels may also contain assay reagents 140 (e.g. dried INVADER assay reagents). The volume of the chamber 40 is preferably larger than the channel 30 such that when the gas inside the chamber, which may be pre-heated, cools it is able to draw liquid from the sample loading port 60 into the channel 30 (e.g. using the principles of the universal or ideal gas law).

FIG. 3 shows a sample processing device or system 10, with a plate component 20 with a top surface 25, and a bottom surface 26. FIG. 3 shows a side view of the plate component 20 with a sealable cover component 70 added that encloses the chambers 40 and channels 30 to form enclosed micro-reactors 56. The sealable cover component 70 may be, for example, a flexible film (e.g. foil) and may be firmly attached to the surface of the plate component 20 such enclosed channels and chambers are formed. Preferably, at least a portion of the sealable cover component 70 is able to change shape (e.g. by melting) such that it can seal off the channel 30 from the chamber 40 and sample loading port 60. For example, a portion of the sealable cover component 70 may seal of the first end 31 and second 32 of the channel 30 after sample has entered the channel 30. The sealable cover component 70 may have an indentation 111 at or near the sample loading port 60. This indentation 111 helps to maximize the contact of the sample with the open ends of the channels 30.

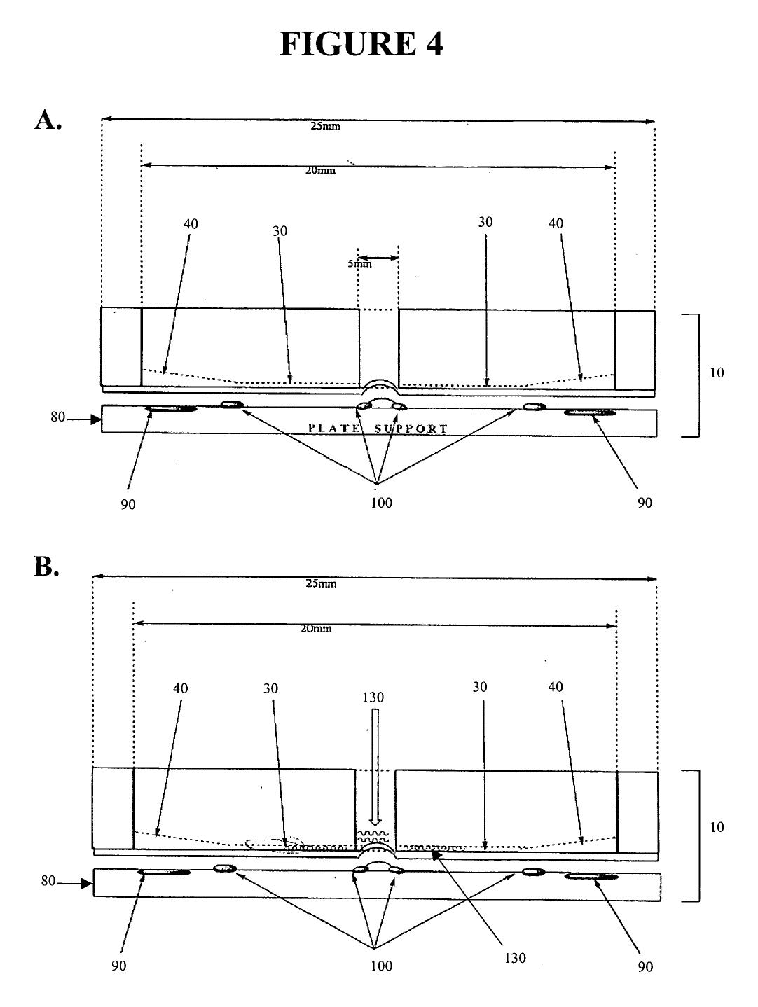

FIG. 4A shows a sample processing device or system 10 with a plate support component 80, containing various channel sealing elements 100 and chamber temperature control elements 90. The plate support component 80 may be seated under the plate component 20 (e.g. with the sealable cover component 70 in between) such that the various channel sealing elements 100 are situated near the first and second ends of each channel 30, and such that the various chamber temperature control elements 90 are situated near the chambers 40 (e.g. such that the gas in the chambers can be heated and/or cooled by the chamber temperature control elements). In certain embodiments the temperature control elements 90 are used to heat the gas in the chambers 40 prior to sample being loaded in the sample loading port causing the air in the chambers and channels to expand.

When sample 130 is loaded, as shown in FIG. 4B, the gas in the chambers 40 is allowed (or made) to cool, thereby causing at least part of the sample 130 in the sample loading port to be drawn in the channels 30. Once the sample 130 is in the channels 30, the first and second ends 31 and 32 of the channels may be sealed using the channel sealing elements 100. The channel sealing elements 100 may cause part of the sealable cover component 70 to at least partially liquefy allowing the first and/or second ends of the channels to be sealed (e.g., such that an assay may be carried out in the sealed channel without contaminating other channels which may be configured to perform different assays).

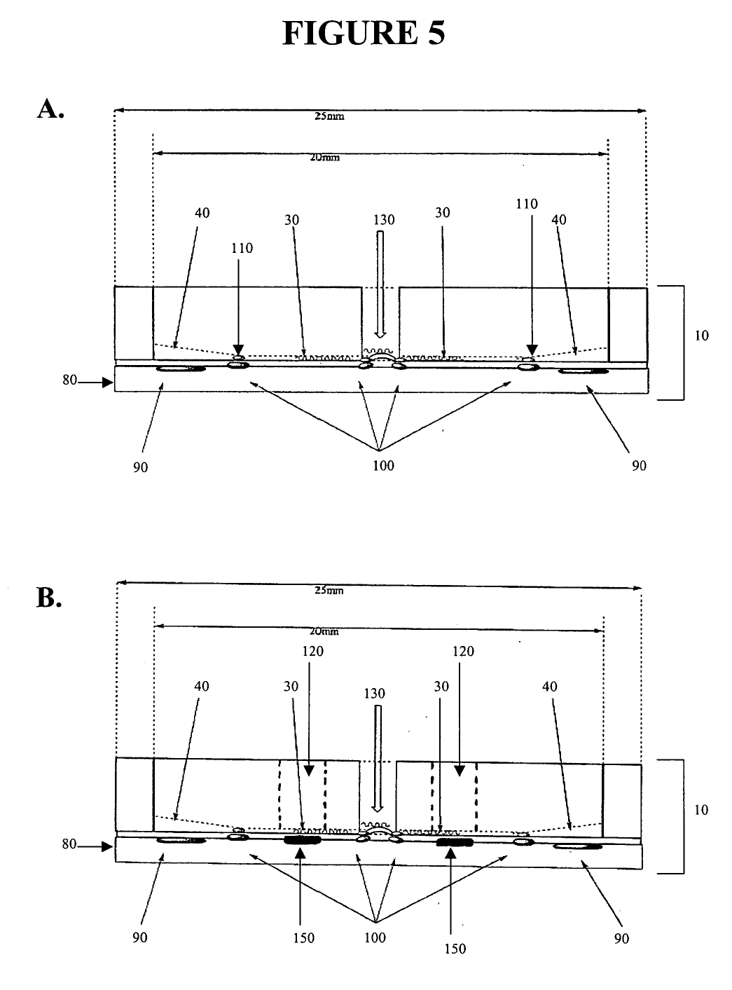

FIG. 5A shows an assembled sample processing device or system 10, including sealable material 110 located within a channel 30. The channel sealing elements 100 located in the plate support 80 may be used to at least partially liquefy or deform the sealable material 110 such that the ends (31 and 32) of the channel 30 are sealed. FIG. 5B shows an assembled sample processing device 10, where the plate support component 80 includes channel temperature control elements 150. Channel temperature control elements 150 may be used, for example, to change the temperature in the channel. This is useful, for example, when sample 130 is sealed in the channel 30 (e.g. for detection assays that require a certain temperature or certain temperature changes).

II. Sample Processing Devices and Systems

The present invention provides novel sample processing devices and systems that, in some embodiments, utilize the phenomenon of expansion and contraction of air and liquid volumes dues to heating and cooling (e.g. at atmospheric pressure). This phenomenon is generally known as the ideal of universal gas law. In certain embodiments, the sample processing device comprises multiple channels (e.g. capillaries) radially oriented around and in fluid communication with a central sample loading port. In some embodiments, the sample processing devices are physically oriented adjacent to precise temperature control elements (e.g. heating elements) which can affect the temperature of air and liquid volumes within the sample processing device. In particular embodiments, the preheating of air inside the sample processing devices enables a liquid sample added to the sample loading port to be drawn inside the micro-reactor system (e.g., composed of a channel and a chamber) upon cooling and subsequent contraction of the air inside the sample processing device. In some embodiments, the sample processing device further comprises sealable material at one or more ends or within interior portions of the channels, that when heated (or otherwise caused to melt) can cause one or more ends, or interior portions, of the micro-reactor to become sealed from fluid communication with other parts of the sample processing device or the outside environment. In certain embodiments, the sample processing device is further configured for use in a signal detection apparatus.

In preferred embodiments, the sample processing devices of the present invention utilize the ideal gas law PV=nRT, where P is pressure, V is volume, n is moles, R is the gas constant 0.0821 liter-atmospheres/K/mole, and T is temperature. According the laws of thermodynamics and the equations of state of materials like water and air, upon heating, a given quantity of liquid or gas will expand in volume if it part of an open system, while a quantity of gas or liquid in a closed system would increase in pressure. The inverse of this principle holds true as well, as a heated quantity of liquid or gas will contract as it cools to come into equilibrium with the temperature of its surrounding environment.

In preferred embodiments of the present invention, air inside a chamber (e.g. part 40 in the Figures) of the sample processing device or system is caused to expand due to the action of chamber temperature control elements (e.g., heating elements) disposed adjacent to the chamber. A liquid sample is added to the sample loading port which is in fluid communication with the micro-reactor and as the heated air in the system cools to match the temperature of the surrounding environment, negative pressure induced by the contraction of this air will draw the liquid into the channels of the sample processing device. Because of the known properties of liquids and gases, precise configuration of volumes of liquids and gases in the chambers and channels can be regulated with precise temperature control. In other words, precise temperature controls can be used to draw in precise quantities of liquids in the channels (or chambers) of the sample processing devices of the present invention. For example, a chamber may be pre-heated to a higher temperature when it is desired to draw a greater volume of sample into the channel associated with the chamber, or the chamber may be pre-heated to a lower temperature to draw a lesser volume of sample into the associated channel.

In certain embodiments, the sample processing device contains a plurality of micro-reactors (e.g., comprising a chamber and a channel) which are disposed in a plate component composed of material such as glass, plastic, or metal. The micro-reactors may be created in the plate component using techniques such as, for example, micro-embossing or micro-etching. In some embodiments, the plate component may be composed of advanced composite materials known in the art with desirable insulation and conductivity characteristics that will allow for precise temperature control and precise rate of temperature change with the outside environment. In particular embodiments, the sample processing device (e.g. with a plurality of micro-reactors) may be constructed such that it becomes a complete (e.g. channels and chambers are enclosed) device upon the addition of a cover layer at a later step in manufacturing. As an example, a system of grooves and pools in a glass slide may become enclosed upon the addition of a cover component (e.g. sealable cover component) that may be a smooth layer of, for example, plastic, foil, glass, or the like, upon the engraved slide. In other embodiments, two halves of the system or device, both comprising engraved or machined layers, may be combined and sealed to form a complete sample processing device or system.

In particular embodiments, the manufactured micro-reactors are disposed against a plate support component which contains various temperature control elements and/or chamber sealing elements. The temperature control elements may, for example, comprise electrically resistive heating and/or cooling elements, or a separate fluidic system containing temperature control liquids or gases, or elements that control temperature through emission of other forms of energy, such as sonic energy, microwave radiation, or the like. In other embodiments, the microreactors may be configured in such a way as to be receptive to focused forms of energy from an outside source for precise temperature control. The device may be configured to received focused energy in the form of laser light, microwave or sonic energy, or the like, from a separate temperature control system.

In some embodiments, additional materials responsive to heat (e.g., sealable material) are disposed at various locations throughout the sample processing device (e.g. in the channels and/or chambers). In particular embodiments, the sealable material comprises meltable foil material, which could be used, for example, at each end of a channel. In certain embodiments, the sealable material is configured with materials that have appropriate conductivity and specific heat properties such that an increase (e.g. sudden increase) in temperature would cause the material to melt, flowing into a channel or chamber. Upon re-cooling (e.g. sudden re-cooling), the material would solidify and effectively seal off a chamber and/or channel from the sample loading port or other part of the sample processing device. Sealing of the liquid volume inside the capillary would also help prevent cross contamination of materials from one microreactor to another. In this way, precise volume of sample could be drawn into a channel, sealed in place, and then further manipulated in any of a variety of chemical or biological reactions.

In certain embodiments, assay reagents of a chemical or biological reaction are predisposed as dried reagents inside the channels and/or chambers. Examples of such reagents include oligonucleotides, solubilization or lysing agents, enzymes (e.g., for amplification, cleavage, or detection), capturing molecules, antibodies, antibody fragments, and the like. In this regard, a single sample volume (e.g. drop of blood) may be added to the sample loading port which is in fluidic communication with a plurality of micro-reactors, each of which may contain the reagents for a separate biological reaction, so that analysis of multiple variables may be obtained at the same time from a single sample in the sample processing device.

In certain embodiments, a plurality of micro-reactors are disposed radially around a sample loading port (e.g. as shown in the Figures). In other embodiments, more complicated capillary channel structures are employed, such as branched channels and the like. In particular embodiments, multiple cycles of heating and cooling the chambers and/or channels is employed such that the liquid sample can be moved from one location to another. In other embodiments, the cooling of the system is accomplished in ways other than radiation of the heat to the surrounding (e.g. cooler) environment through the establishment of thermal equilibrium, such as active cooling through the use of air conditioning, refrigeration, Peltier systems, or the like. In some embodiments, the sample processing devices of the present invention also employ additional methods of flow control, such as valves, motor-driven seals, pumps, and the like. In certain embodiments, the sample is added to the sample loading port before or after heating of the air within system (e.g. within the chambers). For example, if liquid is in place before the chambers are heated, the system may be configured in such a way as to allow the air to escape from the system as it expands from heating either through the liquid sample itself or through a separate venting system. In further embodiments, “on-chip” detection and data analysis systems are combined with the sample processing devices of the present invention in order to generate field-portable, all-in-one diagnostic devices.

Due to the common forces of capillary action, unwanted flow of sample volume in capillary size chambers may need to be prevented in certain embodiments. Examples of design solutions to this potential problem include the use of hydrophobic or positively charged materials that will repel the entry of the liquid sample into the channels. The repulsive forces are preferably less than the force driving the sample in the capillary sized channel upon the negative pressure caused by the cooling air in the chambers, so that precise volume of sample can be drawn into each capillary. In other embodiments, it is noted that the material experiencing expansion and contraction need not necessarily be a gas. For example, a liquid may be predisposed in the sample processing device (e.g. in the chambers and/or channels).

In certain embodiments, the sample processing devices of the present invention are employed in conjunction with a signal detection device. The sample detection device may detect a signal from a reaction in one or more channels via detection ports (e.g. part 120 in FIG. 5). In certain embodiments, the signal detection device is a top-read, fluorescence plate reader (e.g., TECAN, GENios models). Additional features that may be part of the sample processing devices of the present invention are found in the art (see, e.g., U.S. Pat. No. 6,627,159; U.S. Pat. No. 6,720,187; U.S. Pat. No. 6,734,401; U.S. Pat. No. 6,814,935; U.S. Application 2002/0064885; and U.S. Application 2003/0152994; all of which are herein incorporated by reference for all purposes.

III. Preferred Reagents for use with the Sample Processing Devices and Systems

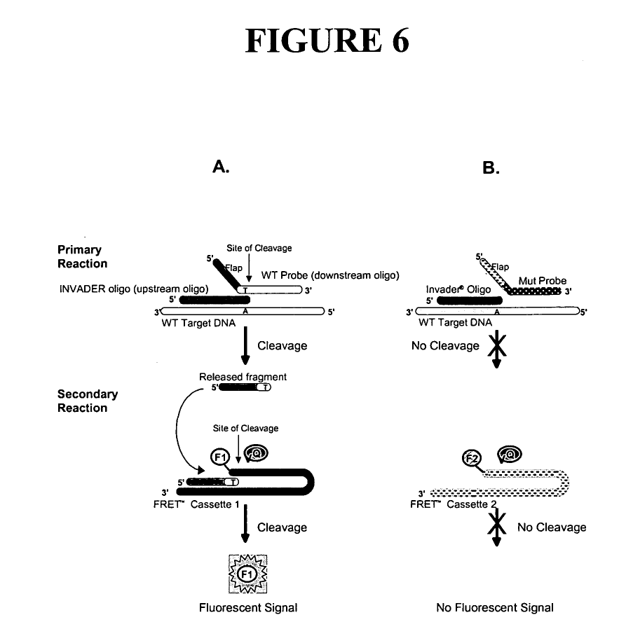

Any type of reagents may be used with the sample processing devices and systems of the present invention, including reagents for INVADER assays, TAQMAN assays, sequencing assays, polymerase chain reaction assays, hybridization assays, hybridization assays employing a probe complementary to a mutation, bead array assays, primer extension assays, enzyme mismatch cleavage assays, branched hybridization assays, rolling circle replication assays, NASBA assays, molecular beacon assays, cycling probe assays, ligase chain reaction assays, or sandwich hybridization assays. In certain embodiments, such reagents are in dried form and pre-loaded in the channels of the sample processing devices (see, e.g., part 140 in FIGS. 2-3). In preferred embodiments, reagents that allow for the formation and cleavage of invasive cleavage structures are employed (e.g. INVADER assay components used for performing INVADER detection assays). These reagents provides nucleotide sequences and enzymes for forming a nucleic acid cleavage structure that is dependent upon the presence of a target nucleic acid (e.g. comprising human target sequence such as shown in FIG. 6) and cleaving the nucleic acid cleavage structure so as to release distinctive cleavage products. 5′ nuclease activity, for example, is used to cleave the target-dependent cleavage structure and the resulting cleavage products are indicative of the presence of specific target nucleic acid sequences in the liquid sample that is loaded into the sample processing device. When two strands of nucleic acid, or oligonucleotides, both hybridize to a target nucleic acid strand such that they form an overlapping invasive cleavage structure, as described below, invasive cleavage can occur. Through the interaction of a cleavage agent (e.g., a 5′ nuclease) and the upstream oligonucleotide, the cleavage agent can be made to cleave the downstream oligonucleotide at an internal site in such a way that a distinctive fragment is produced. Such embodiments have been termed the INVADER assay (Third Wave Technologies) and are described in U.S. Pat. Nos. 5,846,717; 5,985,557; 5,994,069; 6,001,567; 6,913,881; and 6,090,543, WO 97/27214, WO 98/42873, Lyamichev et al., Nat. Biotech., 17:292 (1999), Hall et al., PNAS, USA, 97:8272 (2000), each of which is herein incorporated by reference in their entirety for all purposes). The INVADER assay detects hybridization of probes to a target by enzymatic cleavage of specific structures by structure specific enzymes.

The INVADER assay detects specific DNA and RNA sequences by using structure-specific enzymes (e.g. FEN endonucleases) to cleave a complex formed by the hybridization of overlapping oligonucleotide probes (See, e.g. FIG. 6). Elevated temperature and an excess of one of the probes enable multiple probes to be cleaved for each target sequence present without requiring temperature cycling. In some embodiments, these cleaved probes then direct cleavage of a second labeled probe. The secondary probe oligonucleotide can be 5′-end labeled with fluorescein that is quenched by an internal dye. Upon cleavage, the de-quenched fluorescein labeled product may be detected using a standard fluorescence plate reader.

The INVADER assay detects specific mutations and SNPs in unamplified, as well as amplified, RNA and DNA including genomic DNA. In the embodiments shown schematically in FIG. 6, the INVADER assay uses two cascading steps (a primary and a secondary reaction) both to generate and then to amplify the target-specific signal. For convenience, the alleles in the following discussion are described as wild-type (WT) and mutant (MT), even though this terminology does not apply to all genetic variations. In the primary reaction (FIG. 6, panel A), the WT primary probe and the INVADER oligonucleotide hybridize in tandem to the target nucleic acid to form an overlapping structure. An unpaired “flap” is included on the 5′ end of the WT primary probe. A structure-specific enzyme (e.g. the CLEAVASE enzyme, Third Wave Technologies) recognizes the overlap and cleaves off the unpaired flap, releasing it as a target-specific product. In the secondary reaction, this cleaved product serves as an INVADER oligonucleotide on the WT fluorescence resonance energy transfer (WT-FRET) probe to again create the structure recognized by the structure specific enzyme (panel A). When the two dyes on a single FRET probe are separated by cleavage (indicated by the arrow in FIG. 6), a detectable fluorescent signal above background fluorescence is produced. Consequently, cleavage of this second structure results in an increase in fluorescence, indicating the presence of the WT allele (or mutant allele if the assay is configured for the mutant allele to generate the detectable signal). In preferred embodiments, FRET probes having different labels (e.g. resolvable by difference in emission or excitation wavelengths, or resolvable by time-resolved fluorescence detection) are provided for each allele or locus to be detected, such that the different alleles or loci can be detected in a single reaction. In such embodiments, the primary probe sets and the different FRET probes may be combined in a single assay, allowing comparison of the signals from each allele or locus in the same sample.

If the primary probe oligonucleotide and the target nucleotide sequence do not match perfectly at the cleavage site (e.g., as with the MT primary probe and the WT target, FIG. 6, panel B), the overlapped structure does not form and cleavage is suppressed. The structure specific enzyme (e.g., CLEAVASE VIII enzyme, Third Wave Technologies) used cleaves the overlapped structure more efficiently (e.g. at least 340-fold) than the non-overlapping structure, allowing excellent discrimination of the alleles.

In the INVADER assays, the probes turn can over without temperature cycling to produce many signals per target (i.e., linear signal amplification). Similarly, each target-specific product can enable the cleavage of many FRET probes. The primary INVADER assay reaction is directed against the target DNA (or RNA) being detected. The target DNA is the limiting component in the first invasive cleavage, since the INVADER and primary probe are supplied in molar excess. In the second invasive cleavage, it is the released flap that is limiting. When these two cleavage reactions are performed sequentially, the fluorescence signal from the composite reaction accumulates linearly with respect to the target DNA amount.

In certain embodiments, the INVADER assay, or other nucleotide detection assays, are performed with accessible site designed oligonucleotides and/or bridging oligonucleotides. Such methods, procedures and compositions are described in U.S. Pat. No. 6,194,149, WO9850403, and WO0198537, all of which are specifically incorporated by reference in their entireties. In certain embodiments, the target nucleic acid sequences are amplified prior to detection (e.g. such that amplified products are generated). In some embodiments, the target nucleic acid comprises genomic DNA. In other embodiments, the target nucleic acid comprises synthetic DNA or RNA. In some preferred embodiments, synthetic DNA within a sample is created using a purified polymerase. In some preferred embodiments, creation of synthetic DNA using a purified polymerase comprises the use of PCR. In other preferred embodiments, creation of synthetic DNA using a purified DNA polymerase, suitable for use with the methods of the present invention, comprises use of rolling circle amplification, (e.g., as in U.S. Pat. Nos. 6,210,884, 6,183,960 and 6,235,502, herein incorporated by reference in their entireties). In other preferred embodiments, creation of synthetic DNA comprises copying genomic DNA by priming from a plurality of sites on a genomic DNA sample. In some embodiments, priming from a plurality of sites on a genomic DNA sample comprises using short (e.g., fewer than about 8 nucleotides) oligonucleotide primers. In other embodiments, priming from a plurality of sites on a genomic DNA comprises extension of 3′ ends in nicked, double-stranded genomic DNA (i.e., where a 3′ hydroxyl group has been made available for extension by breakage or cleavage of one strand of a double stranded region of DNA). Some examples of making synthetic DNA using a purified polymerase on nicked genomic DNAs, suitable for use with the methods and compositions of the present invention, are provided in U.S. Pat. Nos. 6,117,634 and 6,197,557, and in PCT application WO 98/39485, each incorporated by reference herein in their entireties for all purposes.

All publications and patents mentioned in the above specification are herein incorporated by reference as if expressly set forth herein. Various modifications and variations of the invention will be apparent to those skilled in the art without departing from the scope and spirit of the invention. Although the invention has been described in connection with specific preferred embodiments, it should be understood that the invention as claimed should not be unduly limited to such specific embodiments. Indeed, various modifications of the described modes for carrying out the invention that are obvious to those skilled in relevant fields are intended to be within the scope of the following claims.

We claim:

1. A sample processing system comprising;
a) a plate component, wherein said plate component comprises;
i) a top surface and a bottom surface;
ii) a sample loading port extending from said top surface to said bottom surface, and
iii) a plurality of un-enclosed micro-reactors formed in said bottom surface, wherein each of said un-enclosed micro-reactors comprises;
A) a chamber, and
B) a channel, wherein said channel comprises a first channel end adjacent to said chamber and a second channel end adjacent to said sample loading port, and
b) a cover component, wherein said cover component is configured to attach to said bottom surface of said plate component such that a plurality of enclosed micro-reactors are generated.

2. The system of claim 1, wherein said chambers have a larger volume than said channels.

3. The system of claim 1, wherein said cover component is a sealable cover component.

4. The system of claim 1, wherein said cover component is attached to said plate component.

5. The system of claim 1, wherein said cover component is not attached to said plate component.

6. The system of claim 1, wherein each of said channels comprise dried assay reagents.

7. The system of claim 1, wherein said channels are in fluidic communication with said sample loading port and said chamber.

8. The system of claim 1, wherein said system further comprises sealable material, wherein said sealable material is located at said first channel end, said second channel end, or both said first and second channel ends.

9. The system of claim 1, further comprising a plate support component configured to be secured to said bottom surface of said plate component such that at least a portion of said cover component is between said plate support component and said plate component.

10. The system of claim 9, wherein said plate support component comprises a plurality of channel sealing elements.

11. The system of claim 10, wherein said plurality of channel sealing elements are located near said first and second channel ends when said plate component is secured to said bottom surface of said plate component.

12. The system of claim 10, wherein said channel sealing elements are configured to heat at a portion of said cover component.

13. The system of claim 9, wherein said plate support component comprises a plurality of chamber temperature control elements.

14. The system of claim 13, wherein said plurality of chamber temperature control elements are located near said chambers when said plate component is secured to said bottom surface of said plate component.

15. The system of claim 14, wherein said chamber temperature control elements are capable of causing gas inside said chambers to expand or contract.

16. The system of claim 14, further comprising a liquid sample in said sample loading port, wherein said chamber temperature control elements are capable of causing said liquid sample to enter said channels by heating or cooling gas inside said chambers.

17. The system of claim 9, wherein said plate support comprises a plurality of channel temperature control elements.

18. The system of claim 9, wherein said plurality of channel temperature control elements are located near said channels when said plate component is secured to said bottom surface of said plate component.

19. The system of claim 1, wherein said plate component further comprises a plurality of detection ports configured to allow reactions in said channels to be monitored.

20. The system of claim 1, wherein said channels contain a liquid sample.

21. The system of claim 20, wherein said first and second channel ends are sealed such that said liquid sample is contained within said channels.

22. A system comprising;
a) a plate component, wherein said plate component comprises;
i) a top surface and a bottom surface;
ii) a sample loading port extending from said top surface to said bottom surface, and
iii) a plurality of micro-reactors, wherein each of said micro-reactors comprises;
A) a chamber comprising gas at a first temperature, and
B) a channel, wherein said channel comprises a first channel end adjacent to said chamber and a second channel end adjacent to said sample loading port, and
b) a plate support component configured to be secured to said bottom surface of said plate component, wherein said plate component comprises at least one accessory element selected from the group consisting of: a chamber temperature control element, a channel sealing element, and a channel temperature control element.
